(19) United States
(12) Patent Application Publication
(10) Pub. No.: US 2025/0261388 A1
(43) Pub. Date: Aug. 14, 2025

(54) SEMICONDUCTOR DEVICE

(71) Applicant: FUJI ELECTRIC CO., LTD., Kawasaki-shi (JP)

(72) Inventors: Yuki KARAMOTO, Matsumoto-city (JP); Tohru SHIRAKAWA, Matsumoto-city (JP); Kaname MITSUZUKA, Matsumoto-city (JP)

(73) Assignee: FUJI ELECTRIC CO., LTD., Kawasaki-shi (JP)

(21) Appl. No.: 19/193,491

(22) Filed: Apr. 29, 2025

Related U.S. Application Data
(63) Continuation of application No. PCT/JP2024/014435, filed on Apr. 9, 2024.

(30) Foreign Application Priority Data
May 30, 2023 (JP) 2023-089070

(51) Int. Cl. H10D 12/00; H10D 62/10; H10D 62/60; H10D 64/00

(52) U.S. Cl. CPC H10D 12/415; H10D 12/481; H10D 62/107; H10D 62/126; H10D 62/60; H10D 64/112

(57) ABSTRACT

A semiconductor device, including: a semiconductor substrate having an active region and a termination region; a first semiconductor region provided in the semiconductor substrate; a second semiconductor region provided in the active region, between a front surface of the semiconductor substrate and the first semiconductor region; a vertical device structure provided in the active region; an insulating layer that covers the front surface of the semiconductor substrate in the termination region; a voltage withstanding structure provided in the termination region to surround the active region, and including a third semiconductor region; a channel stopper electrode provided on the insulating layer, closer to the semiconductor substrate than is the voltage withstanding structure; and a fourth semiconductor region provided between the front surface of the semiconductor substrate and the first semiconductor region, apart from the third semiconductor region and the contact hole on two sides of the fourth semiconductor region.

### CROSS REFERENCE TO RELATED APPLICATIONS

This is a continuation application of International Application PCT/JP2024/014435 filed on Apr. 9, 2024 which claims priority from a Japanese Patent Application No. 2023-089070 filed on May 30, 2023, the contents of which are incorporated herein by reference.

### BACKGROUND OF THE INVENTION

### 1. Field of the Invention

Embodiments of the invention relate to a semiconductor device.

### 2. Description of the Related Art

In a conventional semiconductor device, a predetermined voltage withstanding structure is provided in an edge termination region that surrounds a periphery of an active region and during reverse bias, electric field applied to main junctions (pn junctions) of the active region is relaxed, whereby a predetermined breakdown voltage is ensured. Further, a channel stopper structure is provided in an outermost periphery of the semiconductor substrate, whereby an occurrence of a parasitic channel due to wiring potential of the front surface of the semiconductor substrate is prevented thereby enhancing reliability of the semiconductor device (for example, refer to International Publication No. WO 2013/132568, Japanese Patent No. 6668687, International Publication No. WO 2014/155565, Japanese Laid-Open Patent Publication No. 2019-087730, and Japanese Laid-Open Patent Publication No. 2016-134411).

### SUMMARY OF THE INVENTION

According to an embodiment of the present disclosure, a semiconductor device, includes: a semiconductor substrate having an active region and a termination region surrounding a periphery of the active region in a plan view of the semiconductor device, the semiconductor substrate having a front surface and a back surface opposite each other; a first semiconductor region of a first conductivity type, provided in the semiconductor substrate, spanning the active region and the termination region; a second semiconductor region of a second conductivity type, provided in the active region of the semiconductor substrate, between the front surface of the semiconductor substrate and the first semiconductor region, thereby forming a pn junction between the second semiconductor region and the first semiconductor region; a vertical device structure provided in the active region and through which a current flows between the front surface and the back surface of the semiconductor substrate, the current passing through the pn junction; an insulating layer that covers the front surface of the semiconductor substrate in the termination region, the insulating layer having a contact hole formed therein; a voltage withstanding structure provided in the termination region to surround the periphery of the active region in the plan view, the voltage withstanding structure being between the front surface of the semiconductor substrate and the first semiconductor region, and including a third semiconductor region of the second conductivity type; a channel stopper electrode provided on the insulating layer, closer to an end of the semiconductor substrate than is the voltage withstanding structure, the channel stopper electrode being in contact with the front surface of the semiconductor substrate via the contact hole in the insulating layer; and a fourth semiconductor region of the first conductivity type, provided between the front surface of the semiconductor substrate and the first semiconductor region, apart from the third semiconductor region and the contact hole that are on two sides of the fourth semiconductor region, the fourth semiconductor region being directly below an inner end of the channel stopper electrode via the insulating layer and having a dopant concentration that is higher than a dopant concentration of the first semiconductor region.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a plan view depicting a layout when a semiconductor device according to an embodiment is viewed from a front surface of a semiconductor substrate thereof.

FIG. 2 is an enlarged view of a portion surrounded by a rectangular frame A in FIG. 1.

FIG. 3 is a cross-sectional view depicting a structure of the semiconductor device according to the embodiment.

FIG. 4 is a cross-sectional view depicting another example of the structure of the semiconductor device according to the embodiment.

FIG. 5 is a cross-sectional view depicting another example of the structure of the semiconductor device according to the embodiment.

FIG. 6 is an enlarged view depicting the structure of the active region in FIGS. 3 to 5.

FIG. 7 is an enlarged view depicting the structure of the active region in FIGS. 3 to 5.

FIG. 8 is a cross-sectional view depicting a structure of an edge termination region of a semiconductor device of a reference example.

### DETAILED DESCRIPTION OF THE INVENTION

First, problems associated with the conventional techniques are discussed. In the conventional techniques, while a voltage withstanding structure and a channel stopper structure are provided based on allowable limits for positive charge and negative charge accumulated in a protective insulating film on a semiconductor substrate in the edge termination region, in International Publication No. WO 2013/132568, Japanese Patent No. 6668687, International Publication No. WO 2014/155565, and Japanese Laid-Open Patent Publication No. 2019-087730, the breakdown voltage of the edge termination region may significantly decrease due to adverse effects of negative charge. Japanese Laid-Open Patent Publication No. 2016-134411 discloses no channel stopper structure having a channel stopper electrode.

Embodiments of a semiconductor device according to the present invention are described in detail with reference to the accompanying drawings.

In the present description and accompanying drawings, layers and regions prefixed with n or p mean that majority carriers are electrons or holes. Additionally, + or − appended to n or p means that the impurity concentration is higher or lower, respectively, than layers and regions without + or −. In the description of the embodiments below and the accompanying drawings, main portions that are identical are given the same reference numerals and are not repeatedly described.

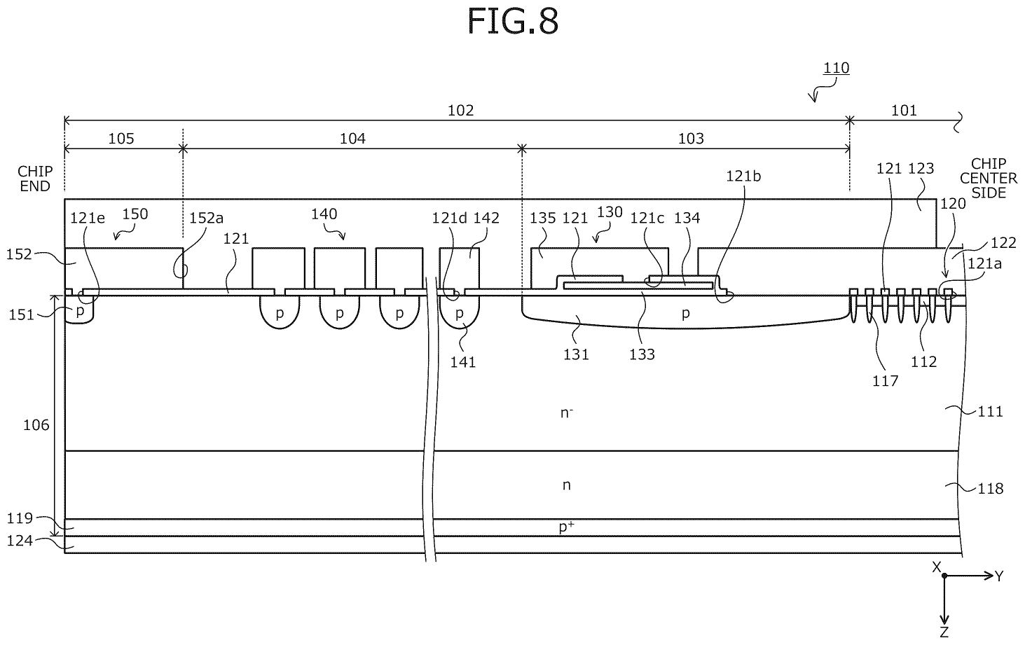

As a result of intensive research, the present inventors have found the following. FIG. 8 is a cross-sectional view depicting a structure of an edge termination region of a semiconductor device of a reference example. A semiconductor device 110 of the reference example depicted in FIG. 8 is a vertical insulated gate bipolar transistor (IGBT) that has a semiconductor substrate 106 containing silicon (Si) as a semiconductor material and having an active region 101 and an edge termination region 102 that surrounds a periphery of the active region 101. In the active region 101, MOS gates (metal-oxide-semiconductor insulated gates) 120 with a general trench gate structure of an IGBT are disposed.

In the edge termination region 102, a gate finger portion 103, a voltage withstanding structure portion 104, and a channel stopper portion 105 are arranged in concentric shapes so as to surround the periphery of the active region 101 sequentially in a direction from the active region 101 to the edge termination region 102 in the order stated. In the gate finger portion 103, a gate finger 130 (a gate polysilicon wiring layer 134 and a gate metal wiring layer 135) are provided on a front surface of the semiconductor substrate 106, via an insulating layer 133. Directly beneath the gate finger 130, a p-type well region 131 is provided in an entire area of the gate finger portion 103, between the front surface of the semiconductor substrate 106 and an n⁻-type drift region 111.

In the voltage withstanding structure portion 104, field limiting rings (FLRs) 141 and field plates (FPs) 142 are provided as a voltage withstanding structure 140. The voltage withstanding structure 140 is designed with consideration of manufacturing process variation with respect to allowable limits (range of an allowable amount of surface charge) for the amount of positive charge and the amount of negative charge that accumulate over time due to high-temperature and high-voltage stress on the FPs 142 and in an insulating layer (the insulating layer 133, an interlayer insulating film 121, and a surface protecting film 123) on the front surface of the semiconductor substrate 106 in the edge termination region 102.

The FLRs 141 are p-type regions with a floating potential and are provided between the front surface of the semiconductor substrate 106 and the n-type drift region 111, apart from the p-type well region 131. The FLRs 141 are provided apart from each other, in concentric shapes surrounding a periphery of the p-type well region 131 in a plan view. The FPs 142 are metal electrodes in contact with the FLRs 141 and having a floating potential; the FPs 142 are provided on the front surface of the semiconductor substrate 106, apart from the gate metal wiring layer 135; the number of the FPs 142 provided and the number of the FLRs 141 provided are equal. The FPs 142 are provided apart from each other, in concentric shapes surrounding a periphery of the gate finger portion 103 in a plan view.

In the channel stopper portion 105, a p-type channel stopper region 151 and a channel stopper electrode 152 are provided as a channel stopper structure 150. The p-type channel stopper region 151 is provided between the front surface of the semiconductor substrate 106 and the n-type drift region 111; the p-type channel stopper region 151 is apart from the FLRs 141 and surrounds a periphery of the FLRs 141 in a plan view. The channel stopper electrode 152 is provided apart from the FPs 142 and surrounds a periphery of the voltage withstanding structure portion 104 in a plan view. The channel stopper electrode 152 is a metal electrode provided on the front surface of the semiconductor substrate 106, at an outermost peripheral portion thereof; the channel stopper electrode 152 is in contact with the p-type channel stopper region 151, which is directly beneath the channel stopper electrode 152.

In general, p-type regions such as the FLRs 141 and the p-type channel stopper region 151 are formed in the edge termination region 102 by ion-implanting a p-type dopant from the front surface of the semiconductor substrate 106 of an n-type, whereby distribution of electric field applied to the edge termination region 102 is controlled. A concentration of the n-type dopant (concentration of the n-type dopant of the n-type drift region 111) of the semiconductor substrate 106 of the n-type is not adjusted and thus, a range of an allowable amount of surface charge is determined according to resistivity of the single crystal silicon of the semiconductor substrate 106 and the voltage withstanding structure portion 104 is designed with consideration of manufacturing process variation with respect to the range of the allowable amount of surface charge.

In this reference structure (the semiconductor device 110), the present inventors confirmed that when simulation is performed under predetermined conditions, electric field concentrates directly beneath an inner end 152a (end facing the active region 101) of the channel stopper electrode 152 and the breakdown voltage of the edge termination region 102 significantly decreases. A predetermined condition under which the breakdown voltage of the edge termination region 102 decreases significantly is an instance in which the voltage withstanding structure 140 is set to a condition under which a depletion layer is likely to spread in an outward direction (direction to a chip end) during reverse bias of main junctions of the active region 101 when the IGBT is in an off-state, the predetermined condition being a state in which negative charge accumulates on the FPs 142 and in the insulating layer on the front surface of the semiconductor substrate 106, in the edge termination region 102.

For example, the larger is a width of an outermost one (the one closest to the chip end) of the FLRs 141, the easier the depletion layer spreads in a direction to the chip end. The depletion layer also tends to spread in a direction to the chip end due to an adverse effect of negative charge. As a result of simulating the breakdown voltage of the edge termination region 102 under a condition of the adverse effect of negative charge, the inventors confirmed that as the width of the outermost one of the FLRs 141 is increased, a change occurs in that a breakdown point (point where reach-through occurs due to impact ionization) moves from the active region 101 to directly beneath the inner end 152a of the channel stopper electrode 152 and the breakdown voltage of the edge termination region 102 decreases as the width of the outermost one of the FLRs 141 is increased.

Further, regarding the voltage withstanding structure 140, the design conditions for reducing susceptibility to the adverse effects of positive charge and the design conditions for reducing susceptibility to the adverse effects of negative charge are contradictory to each other and thus, it is difficult to design a structure that is resistant to the adverse effects of both positive charge and negative charge. Thus, one problem addressed in the present embodiment is providing a semiconductor device that has high long-term reliability by stably ensuring a predetermined breakdown voltage by suppressing decreases in the breakdown voltage caused by surface charge that accumulates over time on the FPs and in the insulating layer on the front surface of the semiconductor substrate in the edge termination region due to high temperature and high voltage stress caused by long-term operation of the semiconductor device.

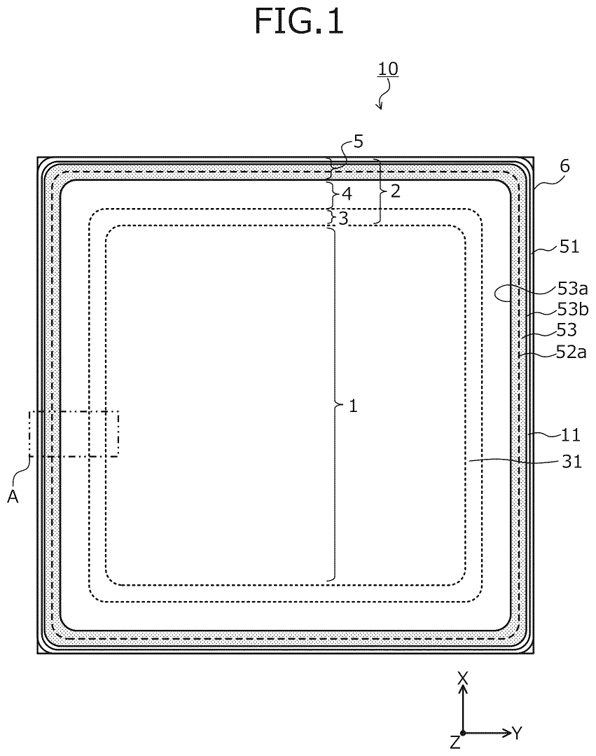

A structure of a semiconductor device according to an embodiment is described. FIG. 1 is a plan view depicting a layout when the semiconductor device according to the embodiment is viewed from a front surface of a semiconductor substrate thereof. In FIG. 1, a border between an active region 1 and an edge termination region 2 (a gate finger portion 3) and a border between the gate finger portion 3 and a withstanding structure portion 4 are indicated by relatively fine dotted lines, an inner end 52a of the channel stopper electrode 52 is indicated by a relatively coarse dashed line, and an n⁺-type channel stopper region 53 is indicated by hatching.

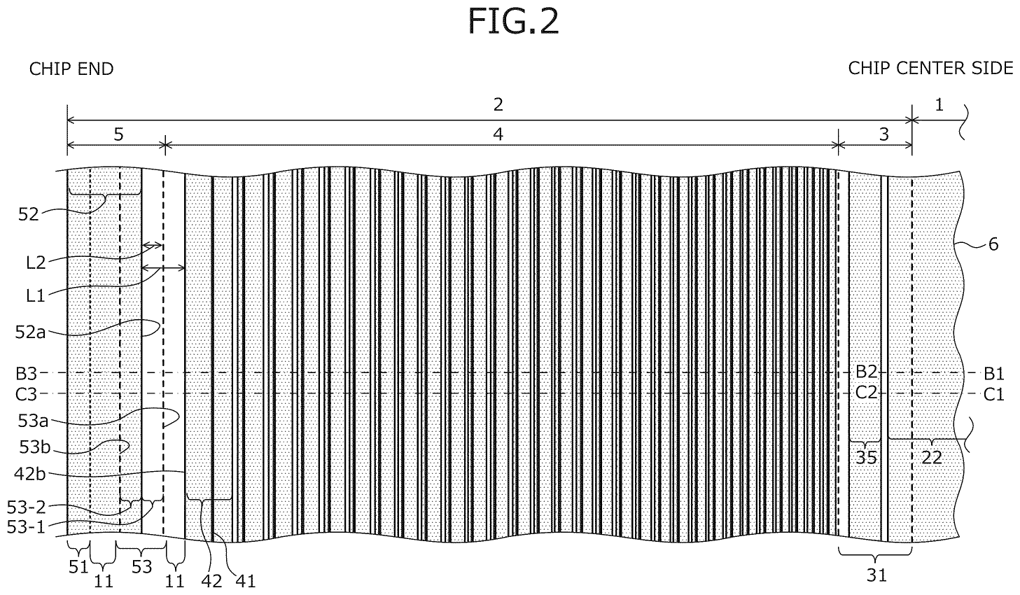

FIG. 2 is an enlarged view of a portion surrounded by a rectangular frame A in FIG. 1. FIG. 2 depicts a layout of the gate finger portion 3, the voltage withstanding structure portion 4, and a channel stopper portion. In FIG. 2, respective ends of a p-type well region 31 and the n⁺-type channel stopper region 53 are indicated by relatively coarse dashed lines, an inner end of a p-type channel stopper region 51 is indicated by a relatively fine dotted line, FLRs 41 are indicated by bold lines, an emitter electrode 22, a gate metal wiring layer 35, FPs 42, and the channel stopper electrode 52 are indicated by a same hatching pattern.

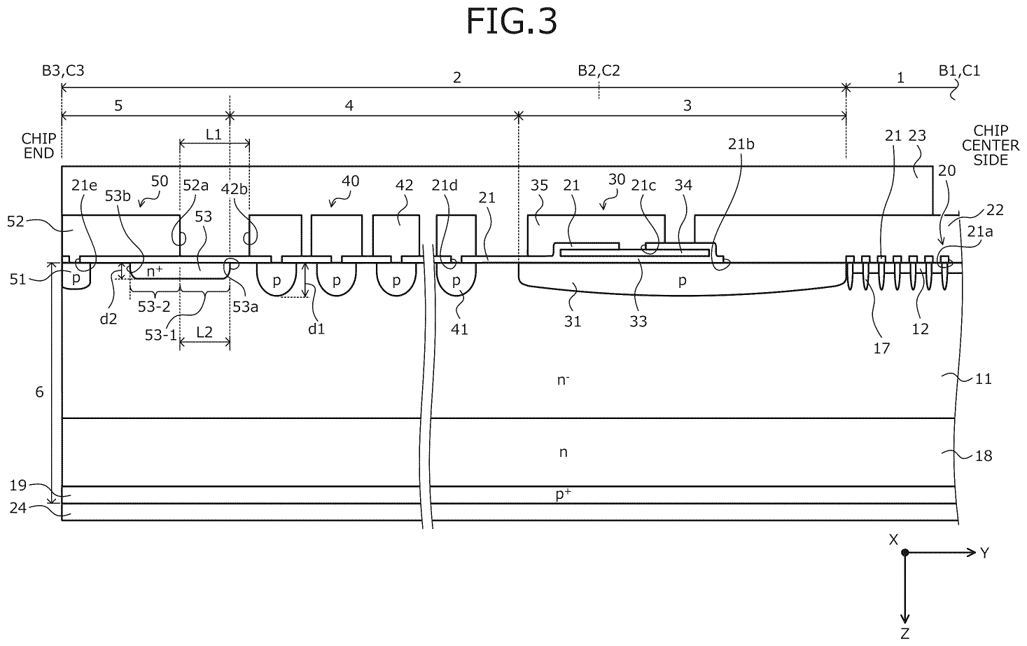

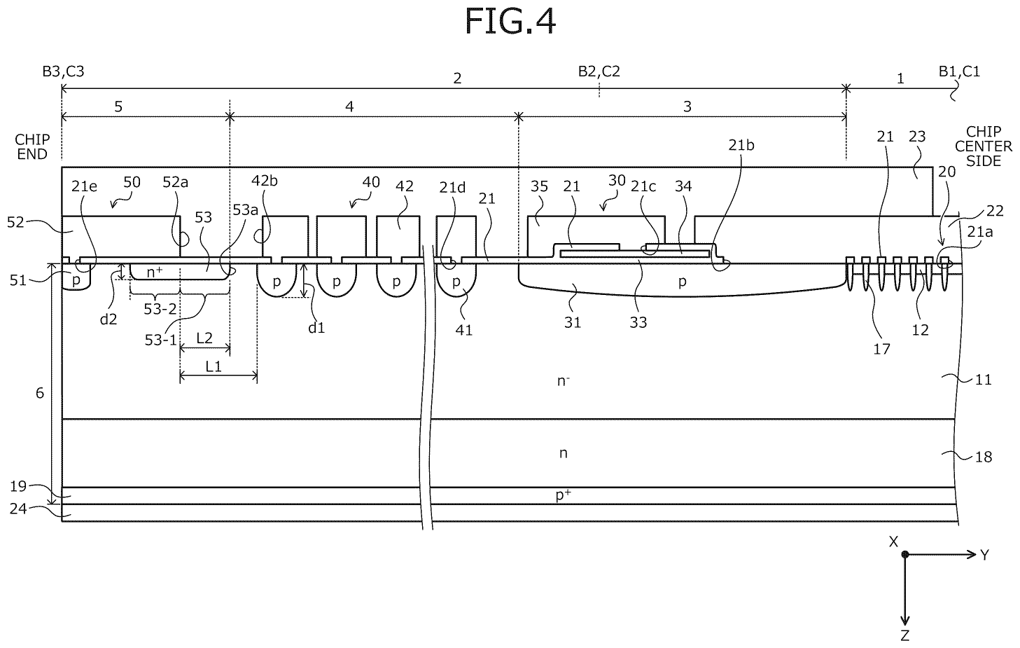

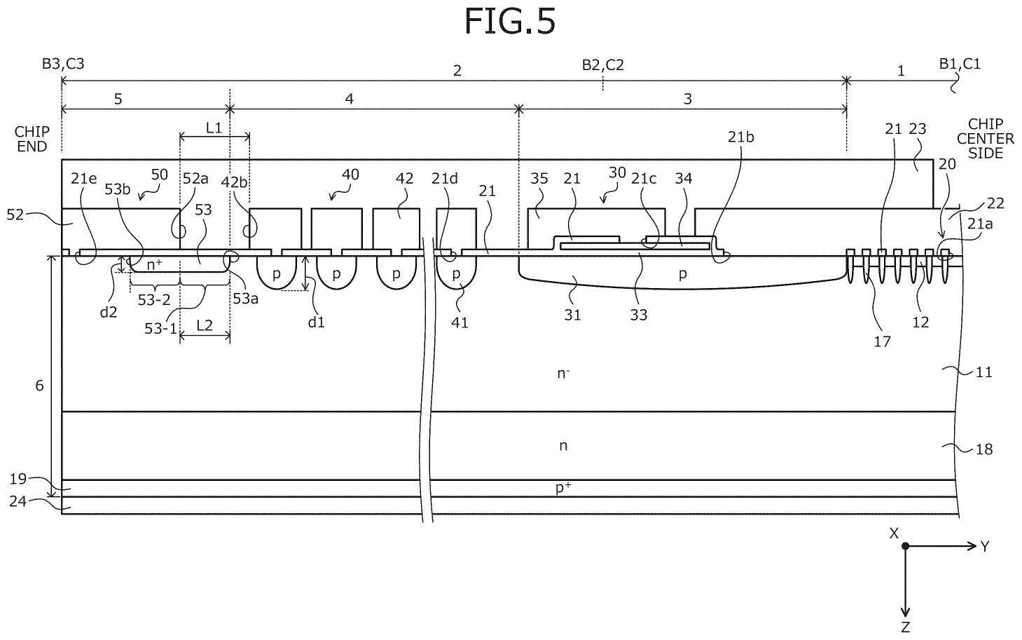

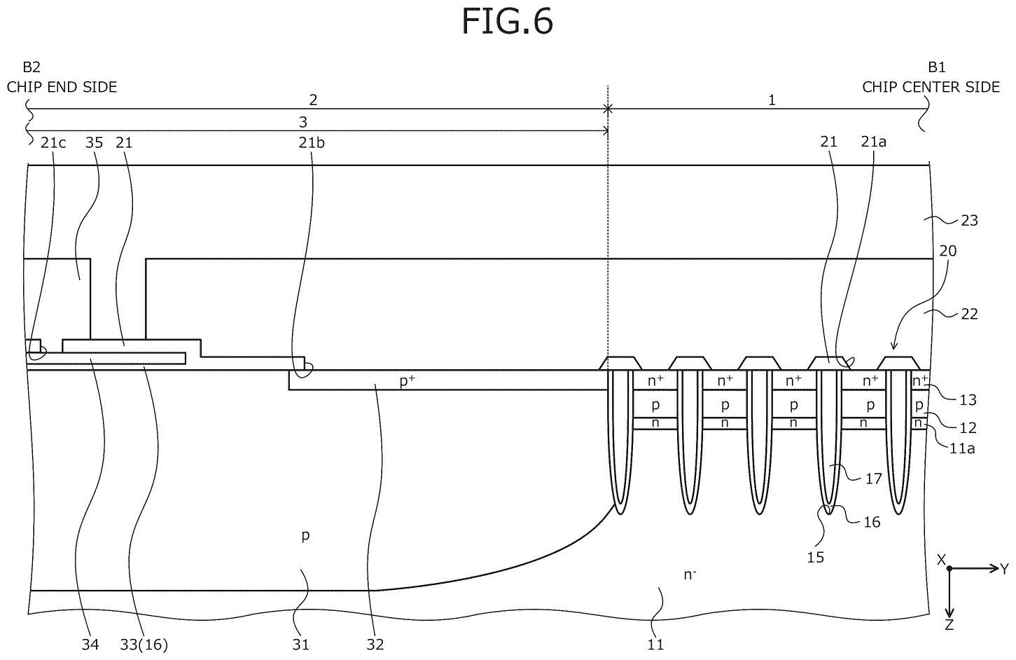

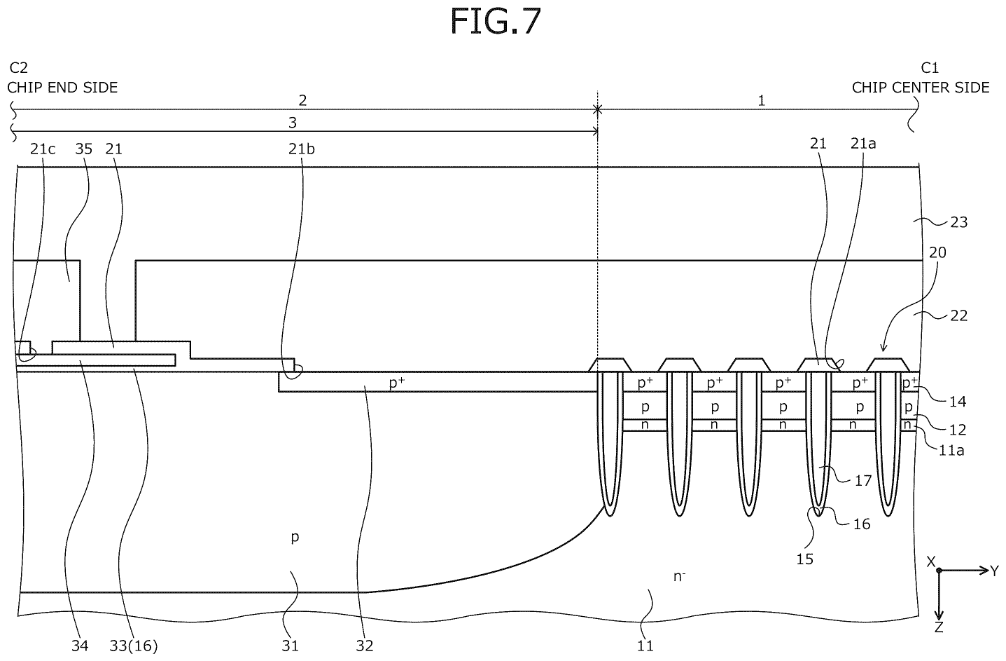

FIG. 3 is a cross-sectional view depicting the structure of the semiconductor device according to the embodiment. FIGS. 4 and 5 are cross-sectional views depicting other examples of the structure of the semiconductor device according to the embodiment. FIGS. 6 and 7 are enlarged views depicting the structure of the active region in FIGS. 3 to 5. In FIGS. 3 to 5, different examples of the structure of the edge termination region 2 are depicted while MOS gates 20 are not depicted. Enlarged cross-sectional views of the structure of the MOS gates 20 are depicted in FIGS. 6 and 7. Further, in FIGS. 3 to 5, some of the FLRs 41 and the FPs 42 are not depicted and a fewer number thereof are depicted than in FIG. 2.

A semiconductor device 10 according to the embodiment depicted in FIGS. 1 to 7 is a vertical IGBT that has a semiconductor substrate (semiconductor chip) 6 containing Si as a semiconductor material and having the active region 1 and the edge termination region 2, which surrounds a periphery of the active region 1 in a plan view. The active region 1 is a region through which a main current (drift current) flows when the IGBT is in the on-state. The active region 1 occupies a majority of an area (surface area) of the semiconductor substrate 6. The active region 1, in a plan view, has a substantially rectangular shape that is substantially a same shape as that of the semiconductor substrate 6 and the active region 1 is provided in substantially a center of the semiconductor substrate 6.

In the active region 1, multiple unit cells (functional units of a device) each having a same IGBT structure (device structure) are disposed adjacent to each other. The unit cells of the IGBT include, in the semiconductor substrate 6, at a front surface thereof, the MOS gates 20 that have a general trench gate structure formed by a p⁻ type base region (second semiconductor region) 12, n⁺-type emitter regions 13, p⁺-type contact regions 14, trenches 15, gate insulating films 16, and gate electrodes 17. The MOS gates 20 are provided between the front surface of the semiconductor substrate 6 and the n-type drift region (first semiconductor region) 11.

The semiconductor substrate 6 is an n-type and a portion thereof excluding diffused regions (the p⁻ type base region 12, the n⁺-type emitter regions 13, the p⁺-type contact regions 14, an n-type FS region 18, a p⁺-type collector region 19, the p⁻ type well region 31, an outer peripheral p⁺-type contact region 32, the FLRs 41, the p⁻ type channel stopper region 51, and the n⁺-type channel stopper region 53) formed in the semiconductor substrate 6 by ion implantation, constitutes the n-type drift region 11. A dopant concentration of the n-type drift region 11 is substantially constant from the active region 1 to an end of the semiconductor substrate 6 (chip end).

The p⁻ type base region 12 is provided between the front surface of the semiconductor substrate 6 and the n′-type drift region 11, in an entire area of the active region 1, the p⁻ type base region 12 being in contact with the n-type drift region 11. The n⁺-type emitter regions 13 and the p⁺-type contact regions 14 are each selectively provided between the front surface of the semiconductor substrate 6 and the p⁻ type base region 12. The n-type drift region 11 (or, additionally a later-described CS region 11a), the p⁻ type base region 12, and the n⁺-type emitter regions 13 are in contact with the gate insulating films 16 at sidewalls of the trenches 15.

The n⁺-type emitter regions 13 and the p⁺-type contact regions 14 are in ohmic contact with the emitter electrode 22 at the front surface of the semiconductor substrate 6 and each has a lower surface (surface facing the p⁺-type collector region 19) in contact with the p⁻ type base region 12. For example, between the trenches 15 adjacent to each other, the n⁺-type emitter regions 13 and the p⁺-type contact regions 14 are provided adjacent to each other, repeatedly alternating with each other in a longitudinal direction (later-described first direction X) of the trenches 15. In other words, in a cross-sectional view, the structure depicted in FIG. 6 and the structure depicted in FIG. 7 are disposed repeatedly alternating with each other in the first direction X.

The p⁺-type contact regions 14 may be in contact with the gate insulating films 16 at the sidewalls of the trenches 15. In an outer peripheral portion of the active region 1 (portion thereof near the border of the edge termination region 2), only the p⁺-type contact regions 14 are provided and the outer peripheral portion of the active region 1 is free of the n⁺-type emitter regions 13. The active region 1 is a portion farther inward (closer to the center of the semiconductor substrate 6) than are ends of the trenches 15 in the longitudinal direction of the trenches 15 and farther inward than are outermost ones (ones closest to the end of the semiconductor substrate 6) of the trenches 15 in a lateral direction of the trenches 15 (a second direction Y that is parallel to the front surface of the semiconductor substrate 6 and orthogonal to the first direction X).

In other words, between several (for example, 2 or 3) outer adjacent ones of the trenches 15 in the lateral direction of the trenches 15, only the p⁺-type contact regions 14 extending linearly in the longitudinal direction of the trenches 15 are disposed, each being in contact with the gate insulating films 16 at the sidewalls of the trenches 15 adjacent thereto. Between the remaining adjacent ones of the trenches 15, the n⁺-type emitter regions 13 and the p⁺-type contact regions 14 are disposed repeatedly alternating with each other in the longitudinal direction of the trenches 15 so that the p⁺-type contact regions 14 are disposed in a vicinity of the ends of the trenches 15 in the longitudinal direction thereof.

In the outer peripheral portion of the active region 1, only the p⁺-type contact regions 14 are provided and thus, hole current that is generated in the edge termination region 2 when the IGBT turns off may be pulled out from contacts between the emitter electrode 22 and the p⁺-type contact regions 14 of the outer peripheral portion of the active region 1, similarly to a contact between the emitter electrode 22 and the outer peripheral p⁺-type contact region 32 of the edge termination region 2. The p⁺-type contact regions 14 may be omitted. In this instance, instead of the p⁺-type contact regions 14, the p⁻ type base region 12 reaches the front surface of the semiconductor substrate 6.

Between and in contact with the p⁻ type base region 12 and the n-type drift region 11, the carrier storage (CS) region (sixth semiconductor region) 11a, which has a same conductivity type as a conductivity type of the n-type drift region 11 and a dopant concentration that is higher than a dopant concentration of the n-type drift region 11, may be provided. The n-type CS region 11a constitutes a minority carrier (hole) barrier, minority carriers accumulate directly beneath the p⁻ type base region 12 (side facing the p⁺-type collector region 19) and thus, current density between the collector and emitter increases and an effect of conductivity modulation increases.

The trenches 15 penetrate through the n⁺-type emitter regions 13 (or, additionally, the p⁺-type contact regions 14), the p⁻ type base region 12, and the CS region 11a and terminate in the n-type drift region 11. The trenches 15, for example, extend in a striped pattern in the first direction X parallel to the front surface of the semiconductor substrate 6. In the trenches 15, the gate electrodes 17 containing polysilicon (poly-Si) are provided, via the gate insulating films 16. An interlayer insulating film (insulating layer) 21 is provided in an entire area of the front surface of the semiconductor substrate 6 so as to cover the gate electrodes 17. Configuration may be such that the trenches 15 do not penetrate through the CS region 11a. In this instance, the trenches 15 terminate in the CS region 11a.

The gate insulating films 16 may extend between the interlayer insulating film 21 and the front surface of the semiconductor substrate 6, from on top of the inner walls of the trenches 15. The emitter electrode 22 is provided on the interlayer insulating film 21 in substantially the entire area of the active region 1; the emitter electrode 22 is in ohmic contact with the n⁺-type emitter regions 13 and the p⁺-type contact regions 14 via contact holes 21a in the interlayer insulating film 21, and is electrically connected to said regions and the p⁻ type base region 12. In the emitter electrode 22, a portion thereof exposed in an opening of a surface protecting film (insulating layer) 23 such as a passivation film functions as an emitter pad (electrode pad).

Between a back surface of the semiconductor substrate 6 and the n-type drift region 11, in an entire area of the semiconductor substrate 6, the n-type field stop (FS) region 18 and the p⁺-type collector region 19 common to the IGBT unit cells are provided. The p⁺-type collector region 19 is provided between the back surface of the semiconductor substrate 6 and the n-type FS region 18. The n-type FS region 18 may be omitted. A collector electrode 24 is provided in an entire area of the back surface of the semiconductor substrate 6, is in ohmic contact with the p⁺-type collector region 19, and is electrically connected to the p⁺-type collector region 19.

The edge termination region 2 is a region between the active region 1 and the end of the semiconductor substrate 6 (chip end), the edge termination region 2 surrounds the periphery of the active region 1 in substantially a rectangular shape in a plan view. In the edge termination region 2, sequentially in a direction from the chip center to the chip end, the gate finger portion 3, the voltage withstanding structure portion 4, and the channel stopper portion 5 are disposed in concentric shapes surrounding the periphery of the active region 1 in a plan view. The gate finger portion 3 is adjacent to an outer side of the active region 1. In the gate finger portion 3, between the front surface of the semiconductor substrate 6 and the n-type drift region 11, the p⁻ type well region 31 is provided in an entire area of the gate finger portion 3.

The p⁻ type well region 31 surrounds the periphery of the active region 1 in a substantially rectangular shape; the p⁻ type well region 31 extends inward toward the chip center and reaches the ends of the trenches 15 in the longitudinal direction and reaches the outer sidewalls of the outermost ones of the trenches 15 in the lateral direction. The p⁻ type well region 31 is directly connected or electrically connected to the p⁻ type base region 12 of the active region 1. A depth of the p⁻ type well region 31, for example, is deeper than a depth of the p⁻ type base region 12 and may be deeper than a depth of the trenches 15. The outer peripheral p⁺-type contact region 32 may be provided between the front surface of the semiconductor substrate 6 and the p⁻ type well region 31.

In the gate finger portion 3, the emitter electrode 22 is in ohmic contact with the outer peripheral p⁺-type contact region 32 via a contact hole 21b of the interlayer insulating film 21, and is electrically connected to this region and the p⁻ type well region 31. The contact between the emitter electrode 22 and the outer peripheral p⁺-type contact region 32 has a function of pulling out, to the emitter electrode 22, minority carriers (holes) generated in the n-type drift region 11 of the edge termination region 2 when the IGBT turns off. The contact hole 21b surrounds the periphery of the active region 1 in a substantially rectangular shape.

Further, in the gate finger portion 3, a gate polysilicon wiring layer 34 and the gate metal wiring layer 35 configuring a gate finger 30 are provided closer to the chip end than is the contact hole 21b. The gate finger 30 (the gate polysilicon wiring layer 34 and the gate metal wiring layer 35) surrounds the periphery of the active region 1 in a substantially rectangular shape in a plan view. The gate polysilicon wiring layer 34 is provided on the front surface of the semiconductor substrate 6 via an insulating layer 33. The gate polysilicon wiring layer 34 faces the p⁻ type well region 31 with the insulating layer 33 intervening therebetween.

The insulating layer 33 is provided between the front surface of the semiconductor substrate 6 and the interlayer insulating film 21. The insulating layer 33 is a field oxide film or a stacked film including the gate insulating films 16 and a field oxide film and, for example, extends to the chip end. The gate polysilicon wiring layer 34 is covered by the interlayer insulating film 21. An inner end (inner peripheral end) of the gate polysilicon wiring layer 34 may face the emitter electrode 22 in a depth direction Z with the interlayer insulating film 21 intervening therebetween. The gate electrodes 17 of all the MOS gates 20 are connected to the gate polysilicon wiring layer 34.

The gate polysilicon wiring layer 34, at a portion thereof not depicted, is electrically connected to a gate pad (electrode pad, not depicted). The gate pad is provided on the interlayer insulating film 21 on the front surface of the semiconductor substrate 6, in the active region 1 or the gate finger portion 3; the gate pad is apart from the emitter electrode 22. The gate metal wiring layer 35 is in contact with the gate polysilicon wiring layer 34 via a contact hole 21c of the interlayer insulating film 21. The contact hole 21c surrounds the periphery of the active region 1 in a substantially rectangular shape in a plan view.

The voltage withstanding structure portion 4 is adjacent to an outer side of the gate finger portion 3. The voltage withstanding structure portion 4 is a region from an outer end (outer peripheral end) of the p⁻ type well region 31 to an inner end (inner peripheral end) 53a of the later-described n⁺-type channel stopper region 53. In the voltage withstanding structure portion 4, a predetermined voltage withstanding structure 40 is provided. The voltage withstanding structure 40 has a function of facilitating the spreading of a depletion layer in a direction to the chip end from main junctions of the active region 1 during reverse bias of the main junctions, adjusting the electric field distribution of the edge termination region 2, and relaxing the electric field applied to the ends of the main junctions of the active region 1.

The voltage withstanding structure 40 may be set to conditions (design conditions that cause susceptibility to the adverse effects of negative charge) that tend to cause decreases in the breakdown voltage of the edge termination region 2 due to the negative charge that accumulates on the FPs 42 and in the insulating layer (the insulating layer 33, the interlayer insulating film 21, and the surface protecting film 23) on the front surface of the semiconductor substrate 6 in the edge termination region 2 due to high-temperature and high-voltage stress caused by long-term operation of the semiconductor device 10. Design conditions that cause susceptibility to the adverse effects of negative charge are conditions under which a depletion layer tends to spread in a direction to the chip end from the active region 1 during reverse bias of the main junctions of the active region 1.

A design condition that causes susceptibility to the adverse effects of negative charge is, for example, an instance in which a width (width in a direction from an inner side to an outer side) of each of the FLRs 41 is set to be wide (for example, exceeding about 3.0 μm). A design condition that causes susceptibility to the adverse effects of negative charge is contradictory to a condition that causes susceptibility to the adverse effects of positive charge. Thus, the voltage withstanding structure 40 is set to a condition that causes susceptibility to the adverse effects of negative charge, whereby the susceptibility to the adverse effects of positive charge that accumulates on the FPs 42 and in the insulating layer on the front surface of the semiconductor substrate 6 in the edge termination region 2 may be reduced.

A main junction of the active region 1 is a pn junction between a p⁻ type region (the p⁻ type base region 12) fixed to a potential of the emitter electrode 22 and the n-type drift region 11. Ends of the main junctions (pn junctions fixed to the potential of the emitter electrode 22) of the active region 1 extend to a border between the gate finger portion 3 and the voltage withstanding structure portion 4 due to the p⁻ type well region 31 of the gate finger portion 3. The breakdown voltage is a voltage limit at which even when current between a drain and source increases due to avalanche breakdown by the pn junctions, voltage between the drain and source does not increase any higher.

As the voltage withstanding structure 40, for example, field limiting rings ((FLRs) third semiconductor regions) 41 that are p⁻ type regions with a floating potential and the field plates (FPs) 42 that are metal electrodes with a floating potential are provided. The FLRs 41 are provided between the front surface of the semiconductor substrate 6 and the n′-type drift region 11 in the voltage withstanding structure portion 4, apart from the p⁻ type well region 31. The FLRs 41 are provided apart from each other in concentric shapes surrounding a periphery of the p⁻ type well region 31 in a plan view. The FLRs 41 have a function of relaxing the electric field applied to a Si interface (interface between the interlayer insulating film 21 and the front surface of the semiconductor substrate 6).

The FLRs 41 are in contact with the interlayer insulating film 21 at the front surface of the semiconductor substrate 6 and are each bordered by the n⁻-type drift region 11 in a plan view. Between the FLRs 41 that are adjacent to each other and between an innermost one (a closest one to the chip center) of the FLRs 41 and the p⁻ type well region 31, the n′-type drift region 11 reaches the front surface of the semiconductor substrate 6. For example, respective widths (in a direction from the inner side to the outer side) of the FLRs 41 are substantially the same and intervals between the FLRs 41 are relatively wider the closer the FLRs 41 are to the chip end. The FLRs 41 all have substantially a same dopant concentration. The dopant concentration of the FLRs 41, for example, is substantially the same as a dopant concentration of the p⁻ type well region 31.

On the front surface of the semiconductor substrate 6 in the voltage withstanding structure portion 4, the FPs 42 equal in number to the number of the FLRs 41 are provided apart from the gate metal wiring layer 35. The FPs 42 are provided apart from each other in concentric shapes surrounding the periphery of the gate finger portion 3 in a plan view. The FPs 42 are in contact with the FLRs 41, respectively, via contact holes 21d of the interlayer insulating film 21. The FPs 42 have a function of externally discharging and reducing fixed charges of the Si interface. The FPs 42 may control the spreading of a depletion layer that spreads from the main junctions in a direction from the active region 1 to the chip end during reverse bias of the active region 1.

The FPs 42 extend on the interlayer insulating film 21, from inside the contact holes 21d. The FPs 42 and the FLRs 41 face each other in the depth direction, respectively and each of the FPs 42 may partially extend (on the interlayer insulating film 21) closer to the chip center and closer to the chip end than is the respective one of the FLRs 41 directly therebelow. The FPs 42 extend closer to the chip center than are the FLRs 41 directly therebelow, whereby spreading of the depletion layer toward the chip end is suppressed directly beneath inner ends (inner peripheral ends) of the FPs 42. The FPs 42 extend closer to the chip ends than are the FLRs 41 directly therebelow, whereby spreading of the depletion layer toward the chip end is facilitated directly beneath outer ends (outer peripheral ends) of the FPs 42.

The amount that each of the FPs 42 extends closer to the chip center and the amount that each of the FPs 42 extends closer to the chip end than are the FLRs 41 is suitably set according to a required breakdown voltage of the edge termination region 2 and may differ among the FPs 42. The inner ends or the outer ends (or both) of the FPs 42 may terminate on the FLRs 41 directly therebelow, respectively, via the interlayer insulating film 21. FIGS. 3 and 4 depict different examples of overhanging of an outermost peripheral one (outermost one) of the outer ends 42b of the FPs 42. Widths (widths in a direction from the chip center to the chip end) of the FPs 42 may differ and the FPs 42 may be arranged in ascending order of width in a direction toward the chip end, for example.

The channel stopper portion 5 is adjacent to an outer side of the voltage withstanding structure portion 4. The channel stopper portion 5 is a region from the inner end 53a of the n⁺-type channel stopper region 53 to the chip end. In the channel stopper portion 5, the channel stopper structure 50 is provided. The channel stopper structure 50 is configured by a p⁻ type channel stopper region (fifth semiconductor region) 51, the channel stopper electrode 52, and the n⁺-type channel stopper region (fourth semiconductor region) 53. The p-type channel stopper region 51 is provided between the front surface of the semiconductor substrate 6 and the n-type drift region 11.

The p⁻ type channel stopper region 51 is provided apart from the outermost one of the FLRs 41, surrounding a periphery of the outermost one of the FLRs 41 in a plan view. The p⁻ type channel stopper region 51 is in contact with the interlayer insulating film 21 at the front surface of the semiconductor substrate 6, is exposed at the chip end, and is bordered by the n-type drift region 11. A depth (depth position of a lower surface) of the p⁻ type channel stopper region 51 is shallower than a depth of the FLRs 41 and, for example, may be in a range of about 4 μm to 6 μm. Instead of the p⁻ type channel stopper region 51, an n-type channel stopper region (not depicted) exposed at the chip end may be provided.

On the front surface of the semiconductor substrate 6 in the channel stopper portion 5, the channel stopper electrode 52, which is fixed at a same potential as the potential of the collector electrode 24, is provided. The channel stopper electrode 52 is provided apart from the FPs 42 and surrounds a periphery of the voltage withstanding structure portion 4 in a plan view. The channel stopper electrode 52 is an outermost metal electrode on the front surface of the semiconductor substrate 6 and faces an entire area of the p⁻ type channel stopper region 51 in the depth direction Z. The channel stopper electrode 52 is in contact with the p⁻ type channel stopper region 51 via a contact hole 21e of the interlayer insulating film 21.

The p⁻ type channel stopper region 51 and the channel stopper electrode 52 have a function of preventing generation of a parasitic channel caused by wiring potential (wiring layer potential drawn in a direction from the chip center side to the chip end) of the front surface of the semiconductor substrate 6. The channel stopper electrode 52 extends on the interlayer insulating film 21, from inside the contact hole 21e toward the chip center and extends closer to the chip center than is the p⁻ type channel stopper region 51. The inner end (inner peripheral end) 52a of the channel stopper electrode 52 terminates on the n⁺-type channel stopper region 53 via the interlayer insulating film 21.

Between the front surface of the semiconductor substrate 6 and the n⁻-type drift region 11, the n⁺-type channel stopper region 53 is provided between the p⁻ type channel stopper region 51 and the outermost one of the FLRs 41. The n⁺-type channel stopper region 53 is provided apart from the FLRs 41 and surrounds the periphery of the outermost one of the FLRs 41 in a plan view. Between the n⁺-type channel stopper region 53 and the outermost one of the FLRs 41, the n-type drift region 11 reaches the front surface of the semiconductor substrate 6. The n⁺-type channel stopper region 53 has an upper surface that is entirely covered by the interlayer insulating film 21.

The n⁺-type channel stopper region 53 is positioned closer to the p⁻ type channel stopper region 51 than is the outermost one of the FLRs 41. The n⁺-type channel stopper region 53 may be in contact with the p⁻ type channel stopper region 51 or may be apart from the p⁻ type channel stopper region 51. In an instance in which the n⁺-type channel stopper region 53 and the p⁻ type channel stopper region 51 are in contact with each other, the dopant concentration of the p⁻ type channel stopper region 51 may be low at portions where the p⁻ type channel stopper region 51 is in contact with the n⁺-type channel stopper region 53 or may partially disappear.

In an instance in which the n⁺-type channel stopper region 53 and the p-type channel stopper region 51 are apart from each other, the n-type drift region 11 reaches the front surface of the semiconductor substrate 6 between the n⁺-type channel stopper region 53 and the p⁻ type channel stopper region 51. An upper surface of the n⁺-type channel stopper region 53 may be positioned closer to the p⁺-type collector region 19 than is the front surface of the semiconductor substrate 6. In this instance, the n-type drift region 11 intervenes between the front surface of the semiconductor substrate 6 and the n⁺-type channel stopper region 53.

The n⁺-type channel stopper region 53 faces the channel stopper electrode 52 in the depth direction Z via the interlayer insulating film 21 and extends closer to the chip center than is the channel stopper electrode 52. In other words, the n⁺-type channel stopper region 53 has an inner-side portion (first portion) 53-1 that does not face the n⁺-type channel stopper region 53 in the depth direction Z and an outer-side portion (second portion) 53-2 directly beneath the channel stopper electrode 52. A width of the outer-side portion 53-2 of the n⁺-type channel stopper region 53 is in a range of 40% to 60% of the entire width of the n⁺-type channel stopper region 53.

In other words, the n⁺-type channel stopper region 53 faces the inner end 52a of the channel stopper electrode 52 in the depth direction Z and is disposed between the channel stopper electrode 52 and an outermost one of the FPs 42. Resistivity of the semiconductor substrate 6 is locally reduced (dose is increased) at a portion thereof where the n⁺-type channel stopper region 53 is provided and outward spreading of the depletion layer directly beneath the inner end 52a of the channel stopper electrode 52 is suppressed, whereby electric field is prevented from concentrating directly beneath the inner end 52a of the channel stopper electrode 52.

The n⁺-type channel stopper region 53 does not face the FPs 42 in the depth direction Z. The inner end (inner peripheral end) 53a of the n⁺-type channel stopper region 53 is positioned between the channel stopper electrode 52 and, the outermost one of the FPs 42 and the outermost one of the FLRs 41. Preferably, a width L2 of the inner-side portion 53-1 of the n⁺-type channel stopper region 53 may be not more than about half of an interval (distance in a direction parallel to the front surface of the semiconductor substrate 6) L1 between the channel stopper electrode 52 and, the outermost one of the FPs 42 or the outermost one of the FLRs 41 (whichever thereof terminates closer to the chip end) (L2≤L½).

For example, in an instance in which the outermost one of the FPs 42 extends closer to the chip end than is the respective one of the FLRs 41 (the outermost one of the FLRs 41) (FIG. 3), the width L2 of the inner-side portion 53-1 of the n⁺-type channel stopper region 53 is not more than about half of the interval L1 between the channel stopper electrode 52 and the outermost one of the FPs 42. In an instance in which the outer end 42b of the outermost one of the FPs 42 terminates on the respective one of the FLRs 41 directly therebelow, the width L2 of the inner-side portion 53-1 of the n⁺-type channel stopper region 53 is less than the interval L1 between the channel stopper electrode 52 and the outermost one of the FLRs 41. In this case, preferably, the width L2 of the inner-side portion 53-1 of the n⁺-type channel stopper region 53 may be not more than about half of the interval L1 between the channel stopper electrode 52 and the outermost one of the FLRs 41 (FIG. 4). Thus, with the described configuration, the shape of the outermost one of the FLRs 41 may be maintained and thus, decreases in the breakdown voltage may be prevented.

When the outer end 42b of the outermost one of the FPs 42 terminates on the respective one of the FLRs 41 directly therebelow, spreading of the depletion layer toward the channel stopper electrode 52 is suppressed and thus, the effect of preventing the electric field from concentrating directly beneath the inner end 52a of the channel stopper electrode 52 increases. Further, by extending the outermost one of the FPs 42 closer to the chip center than is the respective one of the FLRs 41 directly therebelow, spreading of the depletion layer toward the channel stopper electrode 52 is suppressed, whereby the effect of preventing the electric field from concentrating directly beneath the inner end 52a of the channel stopper electrode 52 is enhanced.

Even in an instance in which the outermost one of the FPs 42 and the outermost one of the FLRs 41 terminate at a same position in a direction to the chip end, the width L2 of the inner-side portion 53-1 of the n⁺-type channel stopper region 53 suffices to be not more than about half of the interval L1 between the channel stopper electrode 52 and the outermost one of the FPs 42 (the outermost one of the FLRs 41). In other words, preferably, the inner end 53a of the n⁺-type channel stopper region 53 may be positioned substantially midway between the channel stopper electrode 52 and the outermost one of the FPs 42 or the outermost one of the FLRs 41 (whichever thereof terminates closer to the chip end) or may be positioned closer to the chip end than is the midway.

A depth (depth position of a lower surface) d2 of the n⁺-type channel stopper region 53 is shallower than is a depth (depth position of a lower surface) d1 of the FLRs 41. In particular, preferably, the depth d2 of the n⁺-type channel stopper region 53 may be in a range of about 10% to 60% of the depth d1 of the FLRs 41 (0.1×d1sd2≤0.6×d1). In an instance in which the n⁺-type channel stopper region 53 is apart from the front surface of the semiconductor substrate 6, the depth position of the lower surface of the n⁺-type channel stopper region 53 suffices to satisfy the above condition with respect to the depth d1 of the FLRs 41.

The present inventors confirmed by simulation that the breakdown voltage of the edge termination region 2 decreases as the depth d2 of the n⁺-type channel stopper region 53 increases. For example, in an instance in which the drift region has a super junction (SJ) structure such as that described in Japanese Patent No. 6668687, depletion progresses in a lateral direction (direction parallel to the front surface of the semiconductor substrate), from pn junctions between n-type regions and p⁻ type regions configuring the SJ structure. Thus, even when an n-type region is provided at a relatively deep depth in a vicinity of the end of a semiconductor substrate, spreading of the depletion layer toward the chip end is not inhibited.

On the other hand, in an instance in which the n-type drift region 11 is normal and not a SJ structure such as that in the present embodiment, depletion progresses downward (toward the p⁺-type collector region 19) from the main junctions of the active region 1 and toward the end of the n-type FS region 18 (i.e., toward the p⁺-type collector region 19 of the end of the semiconductor substrate 6) from the ends of the main junctions of the active region 1. Thus, when the depth d2 of the n⁺-type channel stopper region 53 is deep, it is surmised that depletion in a diagonal direction is inhibited near the end of the semiconductor substrate 6.

Thus, when the depth d2 of the n⁺-type channel stopper region 53 is deep and exceeds the upper limit described, spreading of a depletion layer is inhibited by the n⁺-type channel stopper region 53 and thus, the breakdown voltage of the edge termination region 2 decreases. In an instance in which the depth d2 of the n⁺-type channel stopper region 53 is less than the lower limit described, the effect of providing the n⁺-type channel stopper region 53 is not obtained. While not particularly limited, for example, the depth d1 of the FLRs 41 may be in a range of about 5 μm to 10 μm and the depth d2 of the n⁺-type channel stopper region 53 may be in a range of about 1 μm to 3 μm.

The dopant concentration of the n⁺-type channel stopper region 53 is uniquely determined and is independent of the dopant concentrations of other diffused regions and the n-type drift region 11. The dopant concentration of the n⁺-type channel stopper region 53, for example, is less than about 1×10¹⁸/cm³ and preferably, may be in a range of about 1×10¹⁶/cm³ to 5×10¹⁷/cm³. When the dopant concentration of the n⁺-type channel stopper region 53 is 1×10¹⁸/cm³ or higher, a depletion layer easily spreads toward the chip end and electric field concentrates in the n⁺-type channel stopper region 53 and thus, is undesirable.

The n⁺-type channel stopper region 53 is a diffused region formed by ion-implantation of an n-type dopant at the front surface of the semiconductor substrate 6. Distribution of the dopant concentration of the n⁺-type channel stopper region 53 exhibits a peak concentration (maximum value of the dopant concentration) at the front surface of the semiconductor substrate 6 or in the semiconductor substrate 6 (at a relatively shallow depth position in a direction to the p⁺-type collector region 19 from the front surface of the semiconductor substrate 6); and from the depth position of the peak concentration, in a direction to the front surface and a direction to the back surface of the semiconductor substrate 6, the dopant concentration decreases exhibiting Gaussian distribution.

The lower surface of the n⁺-type channel stopper region 53 is assumed to be at a deep first depth position that is located at a halfwidth of the distribution of the dopant concentration from the depth position of the peak concentration, in a direction to the p⁺-type collector region 19; and the upper surface of the n⁺-type channel stopper region 53 is assumed to be at a shallow second depth position that is located at a halfwidth of the distribution of the dopant concentration from the depth position of the peak concentration, in a direction to the front surface of the semiconductor substrate 6. In an instance in which a distance from the depth position of the peak concentration to the front surface of the semiconductor substrate 6 is not more than a halfwidth of the distribution of the dopant concentration, the upper surface of the n⁺-type channel stopper region 53 is assumed to be the front surface of the semiconductor substrate 6.

For example, the n⁺-type channel stopper region 53 may exhibit substantially a same distribution (particularly, the peak concentration) of the dopant concentration as the distribution of the dopant concentration of the CS region 11a. An opening is formed at a predetermined location in an ion implantation mask for forming the CS region 11a, whereby the n⁺-type channel stopper region 53 may be formed concurrently with the CS region 11a without additional processes. Acceleration voltage of the ion implantation for forming the CS region 11a is relatively high in a range of, for example, 2 MeV to 3 MeV and thus, even when the ion implantation is performed to the semiconductor substrate 6 through an initial insulating film, the n⁺-type channel stopper region 53 may be formed having a dopant concentration distribution that is nearly the same as when the ion implantation is performed directly to the semiconductor substrate 6.

The channel stopper structure 50 may be configured by the channel stopper electrode 52 and the n⁺-type channel stopper region 53, omitting the p-type channel stopper region 51 (FIG. 5). In this case, the channel stopper electrode 52 is in contact with the n-type drift region 11 at the front surface of the semiconductor substrate 6 via the contact hole 21e of the interlayer insulating film 21. An outer end (outer peripheral end) 53b of the n⁺-type channel stopper region 53 may extend outward to the chip end and be exposed at the chip end. In FIG. 5, while the FLRs 41 and the FPs 42 of the same configuration as that in FIG. 3 are depicted, the FLRs 41 and the FPs 42 may be disposed in the same configuration as that in FIG. 4.

As the voltage withstanding structure 40, providing at least a p⁻ type region that forms a pn junction with the n-type drift region 11 suffices and instead of the FLRs 41, a junction termination extension (JTE) structure may be provided (not depicted). The JTE structure is a structure in which a single p-type electric field relaxing layer is disposed, the p⁻ type electric field relaxing layer being formed by multiple p⁻ type regions that are arranged in descending order of dopant concentration (or in descending order of depth) in a direction from the chip center to the chip end, the p⁻ type regions being arranged adjacently so as to overlap each other in concentric shapes surrounding the periphery of the active region in a plane view.

An effective dopant concentration of the p⁻-type electric field relaxing layer progressively decreases from the side thereof facing the chip center to the side thereof facing the chip end. The p⁻ type electric field relaxing layer is in contact with the p⁻ type well region 31, between the front surface of the semiconductor substrate 6 and the n-type drift region 11. An entire area of the upper surface of the p⁻ type electric field relaxing layer is covered by the interlayer insulating film 21. In an instance in which the voltage withstanding structure 40 has a JTE structure, the FPs 42 are omitted. A positional relationship between the n⁺-type channel stopper region 53 and the p⁻-type electric field relaxing layer of the JTE structure is a same as a positional relationship between the n⁺-type channel stopper region 53 and the outermost one of the FLRs 41.

Operation of the semiconductor device 10 according to the embodiment is described. Normally, the emitter electrode 22 is grounded or negative voltage is applied thereto. Voltage that is positive with respect to the emitter electrode 22 is applied to the collector electrode 24. Even in this state, when voltage applied to the gate electrodes 17 is lower than a gate threshold, pn junctions (the main junctions of the active region 1) between the p⁻ type base region 12 and the n-type drift region 11 (or the CS region 11a) are reverse biased and thus, current does not flow between the emitter and collector. In other words, the IGBT (the semiconductor device 10) maintains the off-state.

On the other hand, when voltage that is positive with respect to the emitter electrode 22 is applied to the collector electrode 24 and voltage that is at least equal to the gate threshold is applied to the gate electrodes 17, a channel (n-type inversion layer) is formed in portions of the p⁻ type base region 12 along the trenches 15. Electrons that pass through the n⁺-type emitter regions 13 and the channel from the emitter electrode 22 are injected into the n-type drift region 11 and the pn junctions between the p⁺-type collector region 19 and the n-type drift region 11 are forward biased. Thus, holes from the collector electrode 24 are injected into the n-type drift region 11, whereby a main current flows between the emitter and collector (both main surfaces of the semiconductor substrate 6) and the IGBT transitions to the on-state.

The voltage applied to the gate electrodes 17 is again reduced to less than the gate threshold, whereby the channel disappears and the supply of electrons from the emitter electrode 22 to the n⁻-type drift region 11 ceases, whereby the supply of holes from the collector electrode 24 to the n′-type drift region 11 also ceases. As a result, electrons and holes stored in the n⁻-type drift region 11 are discharged to the collector electrode 24 and the emitter electrode 22, respectively, or disappear due to recombination in the n-type drift region 11, whereby the flow of current between the emitter and collector ceases. The IGBT transitions from the on-state to the off-state.

When the IGBT is off, the breakdown voltage of the edge termination region 2 may be enhanced to an extent a depletion layer spreads toward the chip end, in the n-type drift region 11 from the reverse biased main junctions of the active region 1. In this case, even when positive charge accumulates on the FPs 42 or in the insulating layer (the insulating layer 33, the interlayer insulating film 21, and the surface protecting film 23) on the front surface of the semiconductor substrate 6 in the edge termination region 2, the voltage withstanding structure 40 is provided, whereby the breakdown voltage of the edge termination region 2 tends to not be adversely affected by the positive charge. The susceptibility to adverse effects of the positive charge may be further reduced by setting the conditions for the voltage withstanding structure 40 to further facilitate the spreading of a depletion layer outward from the active region 1.

Further, even when negative charge accumulates on the FPs 42 and/or in the insulating layer on the front surface of the semiconductor substrate 6 in the edge termination region 2, a depletion layer directly beneath the inner end 52a of the channel stopper electrode 52 is suppressed from spreading outward by the n⁺-type channel stopper region 53 and the electric field is prevented from concentrating at that portion, whereby the breakdown voltage of the edge termination region 2 may be enhanced. Thus, even when positive or negative charge accumulates on the FPs 42 and/or in the insulating layer on the front surface of the semiconductor substrate 6 in the edge termination region 2 over time due to high temperature and high voltage stress caused by long-term operation of the semiconductor device 10, the predetermined breakdown voltage of the edge termination region 2 may be stably ensured.

The present inventors confirmed by simulation that by providing the n⁺-type channel stopper region 53, high electric field is uniformly applied to substantially an entire area of the n-type drift region 11 in the inner-side portion of the voltage withstanding structure portion 4. High electric field is uniformly applied to the inner-side portion of the voltage withstanding structure portion 4 and thus, it is presumed that the breakdown voltage of the edge termination region 2 increases when negative charge is accumulated because the breakdown point moves inward from directly beneath the inner end 52a of the channel stopper electrode 52. The breakdown voltage of the edge termination region 2 being stable means that the breakdown voltage of the edge termination region 2 does not vary with negative or positive charge and is maintained at not less than the breakdown voltage of the edge termination region 2 under normal conditions (zero charge).

As described, according to the embodiment, the n⁺-type channel stopper region is provided closer to the chip end than is the outermost one of the FLRs; the n⁺-type channel stopper region is provided apart from the outermost one of the FLRs and faces the inner end of the channel stopper electrode in the depth direction. Even when negative charge accumulates on the FPs and/or in the insulating layer on the front surface of the semiconductor substrate in the edge termination region due to high temperature and high voltage stress caused by long-term operation of the semiconductor device, outward spreading of the depletion layer directly beneath the inner end of the channel stopper electrode is suppressed by the n⁺-type channel stopper region and the electric field is prevented from concentrating in the portion. As a result, the breakdown voltage of the edge termination region may be enhanced and thus, a predetermined breakdown voltage of the edge termination region may be stably ensured. Thus, long-term reliability of the edge termination region with respect to negative charge may be enhanced.

Further, according to the embodiment, by making the charge negative and enhancing the breakdown voltage of the edge termination region, it is possible to either increase the tolerance range for FLR manufacturing process variation or reduce the number of FLRs thereby enabling reductions in size.

In the foregoing, the present disclosure is not limited to the embodiments described and various modifications within a range not departing from the spirit of the invention are possible. For example, the present invention is not limited an IGBT and is applicable to a vertical semiconductor device and may be applied to a vertical metal oxide semiconductor field effect transistor (MOSFET) that has insulated gates with a metal-oxide-semiconductor three-layer structure. In this instance, instead of the p⁺-type collector region, an n⁺-type drain region is provided, whereby the MOSFET is formed. In the MOSFET, the CS region is a carrier spreading (CS) region that reduces carrier spreading resistance. Without providing the n⁺-type emitter regions, an n⁺-type cathode region is provided instead of the p⁺-type collector region, whereby a diode is formed.

Further, the present invention is applicable to a reverse blocking IGBT (RB-IGBT) and a reverse conducting IGBT (RC-IGBT) having a diode built into the same semiconductor substrate as is the IGBT. In these instances, a portion of the p⁺-type collector region is replaced with an n⁺-type cathode region, whereby the RC-IGBT is formed; and the p⁻ type channel stopper region is formed to a depth so as to penetrate through the back surface from the front surface of the semiconductor substrate and be exposed at the entire surface of the chip end, whereby the RB-IGBT is formed. Further, the present invention is applicable to a semiconductor such as silicon carbide (SiC) having a band gap that is wider than a band gap of silicon (hereinafter, wide band gap semiconductor). In the embodiments, while a first conductivity type is assumed to be an n-type and a second conductivity type is assumed to be a p⁻ type, the present invention is similarly implemented when the first conductivity type is a p-type and the second conductivity type is an n-type.

According to the invention described, outward spreading of a depletion layer directly beneath the inner end of the channel stopper electrode is suppressed and electric field concentration at the portion is suppressed, whereby even when negative charge is accumulated in the insulating layer, the breakdown voltage of the termination region may be enhanced.

The semiconductor device according to the present invention achieves an effect in that a predetermined breakdown voltage may be stably ensured.

As described, the semiconductor device according to the present invention is useful for power semiconductor devices used in power converting equipment, power source devices of various types of industrial machines, and the like.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor device, comprising:
a semiconductor substrate having an active region and a termination region surrounding a periphery of the active region in a plan view of the semiconductor device, the semiconductor substrate having a front surface and a back surface opposite each other;
a first semiconductor region of a first conductivity type, provided in the semiconductor substrate, spanning the active region and the termination region;
a second semiconductor region of a second conductivity type, provided in the active region of the semiconductor substrate, between the front surface of the semiconductor substrate and the first semiconductor region, thereby forming a pn junction between the second semiconductor region and the first semiconductor region;
a vertical device structure provided in the active region and through which a current flows between the front surface and the back surface of the semiconductor substrate, the current passing through the pn junction;
an insulating layer that covers the front surface of the semiconductor substrate in the termination region, the insulating layer having a contact hole formed therein;
a voltage withstanding structure provided in the termination region to surround the periphery of the active region in the plan view, the voltage withstanding structure being between the front surface of the semiconductor substrate and the first semiconductor region, and including a third semiconductor region of the second conductivity type;
a channel stopper electrode provided on the insulating layer, closer to an end of the semiconductor substrate than is the voltage withstanding structure, the channel stopper electrode being in contact with the front surface of the semiconductor substrate via the contact hole in the insulating layer; and
a fourth semiconductor region of the first conductivity type, provided between the front surface of the semiconductor substrate and the first semiconductor region, apart from the third semiconductor region and the contact hole that are on two sides of the fourth semiconductor region, the fourth semiconductor region being directly below an inner end of the channel stopper electrode via the insulating layer and having a dopant concentration that is higher than a dopant concentration of the first semiconductor region.

2. The semiconductor device according to claim 1, wherein the dopant concentration of the fourth semiconductor region is of a Gaussian distribution in which the dopant concentration decreases from a peak concentration thereof to the front surface of the semiconductor substrate in a depth direction of the semiconductor substrate, and decreases from the peak concentration to the back surface of the semiconductor substrate in the depth direction.

3. The semiconductor device according to claim 2, wherein in the depth direction, a distance from the peak concentration to the front surface of the semiconductor substrate is not more than a halfwidth of the Gaussian distribution.

4. The semiconductor device according to claim 2, wherein in the depth direction, a depth of the fourth semiconductor region is smaller than a depth of the third semiconductor region.

5. The semiconductor device according to claim 4, wherein the depth of the fourth semiconductor region is in a range of 10% to 60% of the depth of the third semiconductor region.

6. The semiconductor device according to claim 1, wherein the fourth semiconductor region has a first portion and a second portion that are mutually exclusive, the first portion being closer to the active region than is the inner end of the channel stopper electrode, and the second portion facing the channel stopper electrode via the insulating layer.

7. The semiconductor device according to claim 6, wherein in a direction parallel to the front surface of the semiconductor substrate, a width of the first portion of the fourth semiconductor region is not more than a half of a distance from the channel stopper electrode to the third semiconductor region.

8. The semiconductor device according to claim 6, wherein
the third semiconductor region is provided in a plurality;
the voltage withstanding structure further has a plurality of metal electrodes provided at the front surface of the semiconductor substrate, equal in number to the plurality of the third semiconductor regions, and being respectively in contact with the plurality of third semiconductor regions, each of the plurality of third semiconductor regions and the plurality of metal electrodes having a floating potential, and
in a direction parallel to the front surface of the semiconductor substrate, a width of the first portion of the fourth semiconductor region is not more than a half of a distance from the channel stopper electrode to an outermost one of the plurality of third semiconductor regions or an outermost one of the plurality of metal electrodes, whichever is closer to the end of the semiconductor substrate.

9. The semiconductor device according to claim 6, wherein in a direction parallel to the front surface of the semiconductor substrate, a width of the second portion of the fourth semiconductor region is in a range of 40% to 60% of a width of the fourth semiconductor region.

10. The semiconductor device according to claim 4, further comprising a fifth semiconductor region provided between the front surface of the semiconductor substrate and the first semiconductor region, closer to the end of the semiconductor substrate than is the fourth semiconductor region, the fifth semiconductor region being in contact with the channel stopper electrode via the contact hole, wherein
in the depth direction, the depth of the fourth semiconductor region is smaller than a depth of the fifth semiconductor region.

11. The semiconductor device according to claim 1, further comprising a fifth semiconductor region provided between the front surface of the semiconductor substrate and the first semiconductor region, closer to the end of the semiconductor substrate than is the fourth semiconductor region, the fifth semiconductor region being in contact with the channel stopper electrode via the contact hole, wherein
in a direction parallel to the front surface of the semiconductor substrate, the fourth semiconductor region is provided closer to the fifth semiconductor region than is the third semiconductor region.

12. The semiconductor device according to claim 11, wherein, the fifth semiconductor region is of the second conductivity type.

13. The semiconductor device according to claim 2, further comprising a sixth semiconductor region of the first conductivity type, provided between the second semiconductor region and the first semiconductor region, the sixth semiconductor region having a dopant concentration higher than the dopant concentration of the first semiconductor region, wherein
the dopant concentration of the sixth semiconductor region has a distribution that is the same as that of the dopant concentration of the fourth semiconductor region.
